(19) United States
(12) Patent Application Publication
(10) Pub. No.: US 2013/0020709 A1
(43) Pub. Date: Jan. 24, 2013

(54) SEMICONDUCTOR PACKAGE AND METHOD OF FABRICATING THE SAME

(71) Applicants: Chun-An Huang, Taichung (TW); Pin-Cheng Huang, Taichung (TW); Chi-Hsin Chiu, Taichung (TW); Shih-Kuang Chiu, Taichung (TW)

(72) Inventors: Chun-An Huang, Taichung (TW); Pin-Cheng Huang, Taichung (TW); Chi-Hsin Chiu, Taichung (TW); Shih-Kuang Chiu, Taichung (TW)

(73) Assignee: SILICONWARE PRECISION INDUSTRIES CO., LTD., Taichung (TW)

(21) Appl. No.: 13/242,940

(22) Filed: Sep. 23, 2011

(30) Foreign Application Priority Data
Jul. 21, 2011 (TW) 100125770

(51) Int. Cl. H01L 23/488; H01L 21/768

(52) U.S. Cl. 257/762; 438/119; 257/E23.023; 257/E21.575

(57) ABSTRACT

A semiconductor package and a method of fabricating the same. The semiconductor package includes a carrier having a plurality bonding pads disposed on a surface thereof, a packaging layer formed on the surface of the carrier and having a plurality of openings corresponding to the bonding pads, a conductive material filled in the openings and electrically connected to the bonding pads, and an electronic component installed on the packaging layer and having a plurality of conductive pillars correspondingly received in the openings and electrically connected to the conductive material. The formation of the openings in the packaging layer can control the position and size of the conductive material to enable the overall height of the conductive structure to be level and to keep the electronic component from tilting.

### BACKGROUND OF THE INVENTION

1. Field of the Invention

This invention relates to semiconductor packages, and, more particularly, to a semiconductor package having a flip-chip structure and a method of fabricating the same.

2. Description of Related Art

In technique of package, comparing to wire bond, the characteristic of flip-chip lies in that chip and substrate are electrically connected by solder bumps rather than gold wires. The advantage of flip-chip is that the density of package is increased and the size of components is reduced. Long gold wires are unnecessary for flip-chip, and thus the electrical performance is improved.

In a currently technique of flip-chip, a plurality of conductive bumps are disposed on electrode pads of a chip, and several pre-solder bumps are disposed on bonding pads of packaging substrate. At temperature of melting pre-solder bumps, reflow pre-solder bump corresponding conductive bumps to form solder connection. Finally, underfilled material couples the chip and packaging substrate, ensuring that completeness and reliability of electrical conduction between the chip and packaging substrate.

Please refer to FIGS. 1A and 1B or other related patents, such as U.S. Pat. No. 7,382,049 and U.S. Pat. No. 7,598,613, disclosing different patterns of flip-chip semiconductor package.

As shown in FIG. 1A, a flip-chip semiconductor package 1a is made by forming a protection layer 101 on a packaging substrate 10 with bonding pads 100. Solder pastes 12 are then applied on the bonding pads 100 so that under bump metallization 131 of semiconductor chip 13 combines with the solder pastes 12 to make a flip-chip combination of semiconductor chip 13 on packaging substrate 10. Finally, underfill 11 is filled between the packaging substrate 10 and the semiconductor chip 13.

As shown in FIG. 1B, another flip-chip semiconductor package 1b is made by forming a protection layer 101 on a packaging substrate 10 with bonding pads 100 and the bonding pads 100 are exposed from protection layer 101. Copper pillars 102 are then disposed on the bonding pads 100. Solder pastes 12 are applied on the copper pillars 102 so that copper pillars 130 of the semiconductor chip 13 are embedded in the solder pastes 12 to make flip-chip combination of the semiconductor chip 13 on the packaging substrate 10. Finally, underfill 11 is filled between the packaging substrate 10 and the semiconductor chip 13.

By the process of combining the solder pastes 12 with the copper pillars 102 and 130, because the solder paste 12 is easily deformed after extrusion, it is not easy to control the height of the overall conductive structure 14a (the UBM 131 and the solder paste 12) and 14b (the copper pillars 102, 130 and the solder paste 12) accurately. A problem of bad flatness of conductive structure 14a, 14b and semiconductor chip 13 to be slant is generated, affecting seriously reliability of electrically connection of follow-up packaging substrate 10 and semiconductor chip 13. When the quantity of the solder pastes 12 is excessive, two adjacent conductive structures 14a, 14b would be short-circuited due to a solder bridge phenomenon.

Besides, it is easily for void phenomenon to occur when underfill 11 is filled between packaging substrate 10 and semiconductor chip 13. The solder pastes 12 may be non-wetting for metal material of UBM 131, causing combination between the solder pastes 12 and the copper pillars 102, 130 to be poor, and even the semiconductor chip 13 may be detached from the packaging substrate 10.

Thus, how to overcome the problems in the prior art is a major issue.

### SUMMARY OF THE INVENTION

In order to overcome the problems in the prior art, the present invention provides a method of fabricating a semiconductor package, comprising: forming a packaging layer on a carrier having a plurality of bonding pads formed thereon, and forming on the packaging layer a plurality of openings corresponding in position to the bonding pads for exposing the bonding pads from the packaging layer; filling the openings with a conductive material electrically connected to the bonding pads; and installing on the packaging layer an electronic component having a plurality of conductive pillars on a surface thereof, the conductive pillars correspondingly received in the openings and electrically connected to the conductive material.

The present invention further provides a semiconductor package, comprising: a carrier having a plurality bonding pads formed thereon; a packaging layer formed on the carrier and having a plurality of openings corresponding in position to the bonding pads for exposing the bonding pads from the packaging layer; a conductive material filled in the openings and electrically connected to the bonding pads; and an electronic component installed on the packaging layer and having a plurality of conductive pillars correspondingly received in the openings and electrically connected to the conductive material.

In the semiconductor package and the method of fabricating the same, the conductive material can be a conductive adhesive or a solder paste, and the position and volume of the conductive material an be controlled by forming the openings in the packaging layer formed on the surface of the carrier. Not only the height of the overall conductive structure can be controlled but also a solder bridge can be prevented.

Besides, it is unnecessary for the disclosed embodiment to use underfill, so a void phenomenon can be prevented. Also, if the conductive material is a conductive adhesive, the combination between the conductive material and the metal can be reinforced to prevent electronic components from being detached from the packaging substrate.

### BRIEF DESCRIPTION OF DRAWINGS

The invention can be more fully understood by reading the following description of the accompanying drawings.

FIG. 1 is a cross-sectional view of a flip-chip semiconductor package according to the prior art; and

FIGS. 2A-2E are cross-sectional views illustrating a method of fabricating a semiconductor package according to the present invention, wherein FIG, 2E′ shows a different embodiment from FIG. 2E.

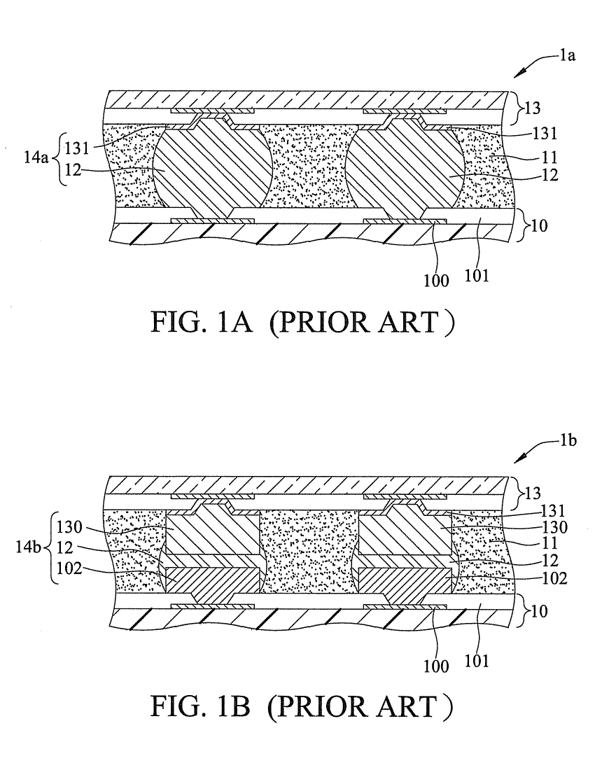

### DETAILED DESCRIPTION OF PREFERRED EMBODIMENTS

The following content explains the method of implementation by concrete embodiments. Those who are familiar with this technical field can easily understand advantages and efficacy of the embodiments disclosed by this description.

Notice that structure, ratio, size and so on in this description are only used to coordinate content disclosed by this description for acknowledgement and reading of those who are familiar this technical field.

Notice that the illustrated structure, ratio and size of appended figures in the explanation are only used for the disclosed embodiments in the explanation for understanding and reading of those who are familiar with this technical field. It is not applicable for limiting implementing condition of the disclosed embodiments, so the illustration doesn't have actual meaning in the technical field. Any modification of structure, change of ratio and adjustment of size should fall in the disclosed embodiments when the efficacy and purpose of the disclosed embodiments are not affected. Meanwhile, the terms that are quoted in the explanation like “on,” “outermost,” “a” and so on only intent for convenience of description rather than limiting feasible scope of the disclosed embodiments. Change or adjustment of relative relationship under no actual alteration of content of technique should be seen as feasible scope of the disclosed embodiments.

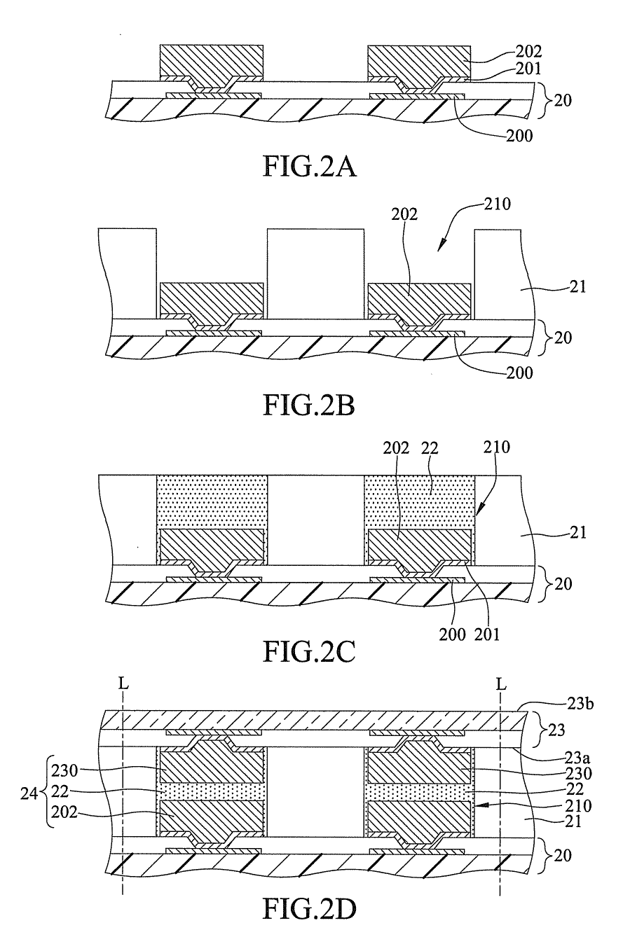

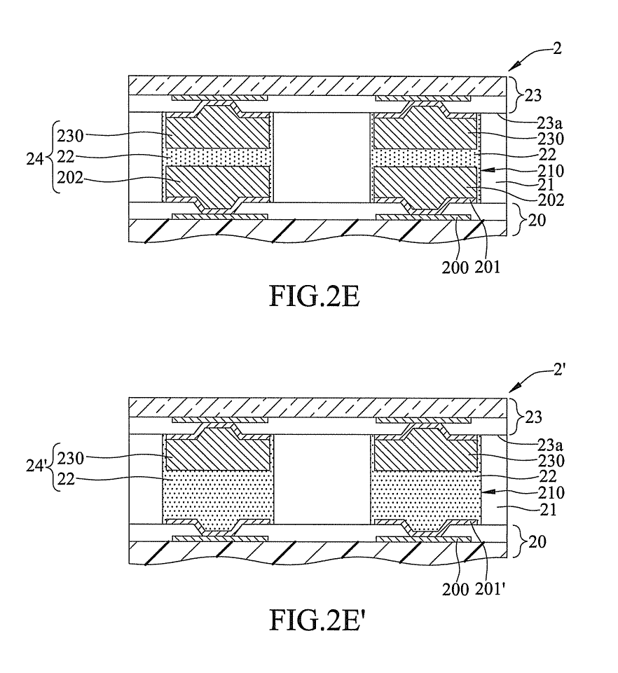

FIGS. 2A to 2E are cross-sectional views illustrating a method of fabricating a semiconductor package 2 according to the present invention.

As shown in FIG. 2A, a carrier 20 having a plurality of bonding pads 200 disposed on a surface thereof is provided.

In an embodiment, the carrier is a wafer, and a metal layer 201 is formed on the bonding pads 200, which is the so-called “Under Bump Metallization” (UBM). Metal pillars 202 are disposed on the metal layer 201, and the metal pillars 202 can be made of copper but not limited thereto. There is no restriction in forming UBM in prior art. In another embodiment, the carrier 20 is a packaging substrate, and metal pillars are disposed on the bonding pads.

As shown in FIG. 2B, a packaging layer 21 is formed on the surface of carrier 20. In an embodiment, the packaging layer 21 is made of a photo-sensitive material such as a dry film.

A patterning process is performed by lithography, to form on the packaging layer 21 a plurality of openings 210 corresponding to the bonding pad 200 for exposing the metal pillars 202.

As shown in FIG. 2C, the openings 210 are filled with a conductive material 22 which is in contact with the metal pillars 202 and the metal layer 201 so as to electrically connect the bonding pad 200.

The conductive material 22 is not in a solid state. In an embodiment, the conductive material 22 is a paste, such as copper or silver paste. For its characteristic of viscose, it is adhesive to any metal material, preventing from a non-wetting phenomenon. In another embodiment, the conductive material can be a solder paste.

As shown in FIG. 2D, an electronic component 23, such as a wafer or a chip is combined with the packaging layer 21. The electronic component 23 can have opposite active surface 23a and non-active surface 23b. A plurality of conductive pillars 230 are disposed on the active surface 23a and correspond to the conductive material 22 correspondingly embedded in the opening 210. Thus, the electronic component 23 and carrier 20 are electrically connected by the conductive material 22. The conductive pillars 230 can be made of copper but not limited thereto.

In an embodiment, openings 210 are formed in the packaging layer 21, to define the position and volume of the conductive material. After the conductive pillars 230 are embedded in the conductive material 22, the conductive material 22, though compressed and deformed, is still restricted by the openings 210. Therefore, the overall height of the conductive structure 24 (i.e., the metal pillars 202, the conductive material 22 and the conductive pillars 230) equals to that of the openings 210, and the height of the conductive structure 24 does not vary with the extrusion and deformation of the conductive material 22.

As shown in FIG. 2E, a singulation process is performed along a cutting line L (as shown in FIG. 2D) to get a plurality of semiconductor packages 2.

In the present invention, the height of the conductive structure 24 is controlled by the openings 210 of the packaging layer 21. The flatness of the surface of conductive structure 24 is ensured so that the electronic component 23 is not slant after flip-chipping and the reliability of electrical connection is also ensured. Due to the separation of the conductive material 22 by the packaging layer 21, the problem of bridge connection of two conductive structures 24 is excluded, so short circuit is avoided.

Besides, by the combination of the packaging layer 21 and the electronic component 23, underfill is needless and the void phenomenon is effectively avoided.

If the conductive material 22 is a conductive paste, the combination of the conductive material 22, the metal pillars 202 and the conductive pillars 230 can be reinforced, avoiding the problems such as non-wetting and weak combination caused in the prior art.

In another embodiment, as shown in FIG. 2E′, in the semiconductor package 2′ it is not necessary to form metal pillars 202 on the bonding pads 200 of the carrier 20, only forming the metal layer 201′ is needed. This way, the metal layer 201′ is exposed from the openings 210 of the packaging layer 21, so that the conductive material 22 can be electrically connected to the carrier 20 by a simple connection to the metal layer 201′. Notice that there is no special restriction in the material of the metal layer 201′.

Thus, as in the process shown in FIG. 2E′, also by the openings 210 of the packaging layer 21 to control the height of conductive structure 24′ (i.e., the conductive material 22 and the conductive pillars 230), the flatness of a surface of the conductive structure 24′ is ensured so that the electronic component 23 is not slant after flip-chipping and the reliability of electrical connection is also ensured. Due to the separation of the conductive material 22 by the packaging layer 21, the problem of bridge connection of two adjacent conductive structures 24′ is excluded, so short circuit is avoided.

Besides, combining the electronic component 23 by the packaging layer 21, underfill is needless, so the “void” phenomenon is avoided.

If the conductive material 22 is a conductive paste, the combination of the conductive material 22 and the conductive pillars 230 can be reinforced, avoiding the problem such as non-wetting and weak combination caused in the prior art.

The present invention also provides a semiconductor package 2, 2′, including: a carrier 20 having a plurality of bonding pads 200 disposed on a surface thereof, a packaging layer 21 formed on the carrier 20 and having a plurality of openings 210, a conductive material 22 filled in the openings 210, and an electronic component 23 combined on the packaging layer 21.

The carrier 20 is a wafer, and metal layers 201, 201′ are disposed on the bonding pads 200. Metal pillars 202 made of copper, for example, can be disposed on the metal layer 201 on demand. In another embodiment, the carrier is a packaging substrate and metal pillars are disposed on the bonding pads.

The packaging layer 21 is photo-sensitive, and the openings 210 correspond to the bonding pads 200.

The conductive material 22 is a conductive paste (e.g., a copper paste or a silver paste) and electrically connected to the bonding pads 200.

The active surface 23a of the electronic component 23 has a plurality of conductive pillars 230 made of copper, for example. The conductive pillars 230 correspond to and are received in the opening 210 to connect the conductive material 22. Side surfaces of the conductive pillars 230 are completely received in the openings 210 to electrically connect the electronic component 23 to the carrier 20.

To sum up, the method according to the present invention includes forms a packaging layer on a carrier to control the height of the conductive material by the openings of the packaging layer. This way, the flatness of the overall height of the conductive structure can be maintained to keep the necessary reliability of electrical connection preventing conductive material from bridge connection. Besides, because underfill is needless, “void” phenomenon is avoided. If the conductive material is a conductive paste, the combination of the conductive material, the metal pillars and the conductive pillars can be reinforced.

The embodiments mentioned above illustratively explain the theory and efficacy of the disclosed embodiments rather than limiting them. Anyone who is familiar with this technical field can make alteration as the spirit and scope of the disclosed embodiments are not violated. The rights protection of this embodiment should be listed as follow.

What is claimed is:

1. A semiconductor package, comprising:
a carrier having a plurality bonding pads formed thereon;
a packaging layer formed on the carrier and having a plurality of openings corresponding in position to the bonding pads for exposing the bonding pads from the packaging layer;
a conductive material filled in the openings and electrically connected to the bonding pads; and
an electronic component installed on the packaging layer and having a plurality of conductive pillars correspondingly received in the openings and electrically connected to the conductive material.

2. The semiconductor package of claim 1, wherein the carrier is a packaging substrate or a wafer.

3. The semiconductor package of claim 1, wherein the carrier further has a plurality of metal pillars formed on the bonding pads.

4. The semiconductor package of claim 3, wherein the metal pillars are copper pillars.

5. The semiconductor package of claim 3, wherein the carrier has a metal layer formed between the bonding pads and the metal pillars.

6. The semiconductor package of claim 1, wherein the carrier has a metal layer formed on the bonding pads.

7. The semiconductor package of claim 1, wherein the packaging layer is a dry film.

8. The semiconductor package of claim 1, wherein the packaging layer is made of a photo-sensitive material.

9. The semiconductor package of claim 1, wherein the conductive material is a conductive adhesive or a solder paste.

10. The semiconductor package of claim 9, wherein the conductive adhesive is made of copper or silver.

11. The semiconductor package of claim 1, wherein the conductive pillars are copper pillars.

12. The semiconductor package of claim 1, wherein the electronic component is a wafer or a chip.

13. A method of fabricating a semiconductor package, comprising:
forming a packaging layer on a carrier having a plurality of bonding pads formed thereon, and forming in the packaging layer a plurality of openings corresponding in position to the bonding pads for exposing the bonding pads from the packaging layer;
filling the openings with a conductive material for the conductive material to be electrically connected to the bonding pads; and
installing on the packaging layer an electronic component having a plurality of conductive pillars thereon, in a manner that the conductive pillars are correspondingly received in the openings and electrically connected to the conductive material.

14. The method of claim 13, wherein the carrier is a packaging substrate or a wafer.

15. The method of claim 13, further comprising disposing metal pillars on the bonding pads of the carrier.

16. The method of claim 15, wherein the metal pillars are made of copper.

17. The method of claim 15, further comprising forming a metal layer between the bonding pads and the metal pillars.

18. The method of claim 13, further comprising forming a metal layer on the bonding pads.

19. The method of claim 13, wherein the packaging layer is a dry film.

20. The method of claim 13, wherein the packaging layer is made of a photo-sensitive material.

21. The method of claim 13, wherein the conductive material is a conductive adhesive or a solder paste.

22. The method of claim 21, wherein the conductive adhesive is made of copper or silver.

23. The method of claim 13, wherein the conductive pillars are copper pillars.

24. The method of claim 13, wherein the electronic component is a wafer or a chip.
